(19) United States
(12) Patent Application Publication
(10) Pub. No.: US 2018/0233580 A1
(43) Pub. Date: Aug. 16, 2018

(54) SEMICONDUCTOR STRUCTURE WITH GATE HEIGHT SCALING

(71) Applicant: GLOBALFOUNDRIES INC., Grand Cayman (KY)

(72) Inventors: Ruilong XIE, Niskayuna, NY (US); John H. ZHANG, Altamont, NY (US); Stan TSAI, Clifton Park, NY (US)

(21) Appl. No.: 15/432,710

(22) Filed: Feb. 14, 2017

(51) Int. Cl. H01L 29/66; H01L 21/3213; H01L 29/423; H01L 21/768; H01L 21/311; H01L 29/78; H01L 29/417; H01L 29/08; H01L 27/088; H01L 29/06; H01L 21/8234

(52) U.S. Cl. CPC H01L 29/66545; H01L 21/32139; H01L 29/42376; H01L 21/76897; H01L 21/31111; H01L 29/66795; H01L 21/823437; H01L 29/41783; H01L 29/0847; H01L 27/0886; H01L 29/0649; H01L 21/823431; H01L 29/7851

(57) ABSTRACT

The present disclosure relates to semiconductor structures and, more particularly, to semiconductor gate structures with gate height scaling and methods of manufacture. The method includes: forming at least one dummy gate structure with hardmask material; forming a plurality of materials over source and drain regions on sides of the at least one dummy gate structure; removing upper materials of the hardmask material such that a first material of the hardmask material remains on the dummy gate structure and in combination with a blocking material of the plurality of materials maintains a uniform gate height; forming a replacement gate structure by removing remaining material of the dummy gate structure to form a trench and depositing replacement gate material in the trench; and forming contacts to the source and drain regions.

### FIELD OF THE INVENTION

The present disclosure relates to semiconductor structures and, more particularly, to semiconductor gate structures with gate height scaling and methods of manufacture.

### BACKGROUND

Transistor scaling has been enabled by pitch scaling and other factors. For example, current scaling elements mainly focus on items that impact foot-print of the transistors, such as gate pitch, channel length, spacer thickness, contact critical dimension (CD), metal pitches and, for advanced technology, fin pitch. However, as the transistor further scales down to a gate pitch of about 50 nm and beyond, different factors (other than foot-print) start to play more significant roles. For example, initial gate height at the 50 nm and beyond starts to play a significant role in scaling.

Due to processes of record, the initial gate height needs to be very tall, e.g., 85 nm and more. This is due mainly to gate height loss resulting from oxide material loss during dummy gate removal and gate pre-clean process, and self aligned gate contact etch processes, as well as subsequent cleaning processes. More specifically, processes of record use interlevel dielectric (ILD) material between adjacent gate structures. This ILD material is an oxide material which is used with the initial gate structure, e.g., dummy gate structure. That is, the initial height of the oxide will correspond with the height of replacement gate structure, after several etching and cleaning processes to remove oxide material.

Due to the processes of record, though, a large budget (thick layer) of ILD is needed for the initial gate height due to oxide material loss during dummy gate removal processes, e.g., using DHF chemistries, and cleaning processes which may damage the surface of the ILD. Moreover, in subsequent processes, e.g., such as self-aligned contact etch processes, it is necessary to etch the oxide ILD with a chemistry selective to a gate cap material (e.g., SiN material); however, the oxide etch selectivity to nitride is not very good which results in additional oxide loss. Accordingly, due to this material loss, the initial height of the replacement gate structure needs to be very tall, which can result in bending and other fabrication issues.

### SUMMARY

In an aspect of the disclosure, a method comprises: forming at least one dummy gate structure with hardmask material; forming a plurality of materials over source and drain regions on sides of the at least one dummy gate structure; removing upper materials of the hardmask material such that a first material of the hardmask material remains on the dummy gate structure and in combination with a blocking material of the plurality of materials maintains a uniform gate height; forming a replacement gate structure by removing remaining material of the dummy gate structure to form a trench and depositing replacement gate material in the trench; and forming contacts to the source and drain regions.

In an aspect of the disclosure, a method comprises: forming at least one dummy gate structure comprising a sacrificial material of a predetermined height and a stack of hardmask materials on the sacrificial material; forming a plurality of materials on source and drain regions on sides of the at least one dummy gate structure; removing upper materials from the stack of hardmask materials, wherein a first material of the stack of hardmask materials remains on the sacrificial material and in combination with a blocking material of the plurality of materials maintains a uniform gate height; exposing the sacrificial material of the at least one dummy structure by removing the first material, while the blocking material maintains the uniform gate height; forming a replacement gate structure which comprises removing the sacrificial material to form a trench and depositing replacement gate material in the trench; and forming contacts to the source and drain regions.

In an aspect of the disclosure, a structure comprises: a fin structure; a replacement gate structure on the fin structure and comprising a capping material on a surface thereof and sidewalls of a same material as the capping material; a raised source region and a raised drain region on sides of the replacement gate structure; a liner material on the sidewalls of the replacement gate structure and above the raised source and drain regions; and a contact in direct electrical contact with the raised source and drain regions and positioned between the liner material of adjacent replacement gate structures.

### BRIEF DESCRIPTION OF THE DRAWINGS

The present disclosure is described in the detailed description which follows, in reference to the noted plurality of drawings by way of non-limiting examples of exemplary embodiments of the present disclosure.

FIG. 1 shows dummy gate structures, amongst other features, and respective fabrication processes in accordance with aspects of the present disclosure.

FIG. 2 shows spacer material on sidewalls of the dummy gate structures, amongst other features, and respective fabrication processes in accordance with aspects of the present disclosure.

FIG. 3 shows exposed material of the dummy gate structures, amongst other features, and respective fabrication processes in accordance with aspects of the present disclosure.

FIG. 4 shows different material layers over the dummy gate structures, amongst other features, and respective fabrication processes in accordance with aspects of the present disclosure.

FIG. 5 shows exposed dummy gate structures, amongst other features, and respective fabrication processes in accordance with aspects of the present disclosure.

FIG. 6 shows trenches (e.g., removed dummy gate structures), amongst other features, and respective fabrication processes in accordance with aspects of the present disclosure.

FIG. 7 shows capped dummy gate structures, amongst other features, and respective fabrication processes in accordance with aspects of the present disclosure.

FIG. 8 shows trenches (e.g., removed dummy gate structures) over a fin structure, amongst other features, and respective fabrication processes in accordance with aspects of the present disclosure.

FIG. 9 shows replacement gate structures in the trenches, amongst other features, and respective fabrication processes in accordance with aspects of the present disclosure.

FIG. 10 shows lined trenches over STI structures, amongst other features, and respective fabrication processes in accordance with aspects of the present disclosure.

FIG. 11 shows filled trenches, amongst other features, and respective fabrication processes in accordance with aspects of the present disclosure.

FIG. 12 shows trenches exposing source and drain regions of the replacement gate structures, amongst other features, and respective fabrication processes in accordance with aspects of the present disclosure.

FIG. 13 shows contacts in electrical contact with the raised source and drain regions, amongst other features, and respective fabrication processes in accordance with aspects of the present disclosure.

### DETAILED DESCRIPTION

The present disclosure relates to semiconductor structures and, more particularly, to semiconductor gate structures with gate height scaling and methods of manufacture. More specifically, the present disclosure provides a gate height smaller than 85 nm of a-Si and 75 nm hardmask material. In more specific embodiments, the present disclosure allows a-Si to be scaled from 85 nm to about 60 nm or less, resulting in replacement gate heights of 60 nm or less.

The semiconductor gate structures of the present disclosure can be manufactured in a number of ways using a number of different tools. In general, though, the methodologies and tools are used to form structures with dimensions in the micrometer and nanometer scale. The methodologies, i.e., technologies, employed to manufacture the semiconductor gate structures of the present disclosure have been adopted from integrated circuit (IC) technology. For example, the structures are built on wafers and are realized in films of material patterned by photolithographic processes on the top of a wafer. In particular, the fabrication of the semiconductor gate structures uses three basic building blocks: (i) deposition of thin films of material on a substrate, (ii) applying a patterned mask on top of the films by photolithographic imaging, and (iii) etching the films selectively to the mask.

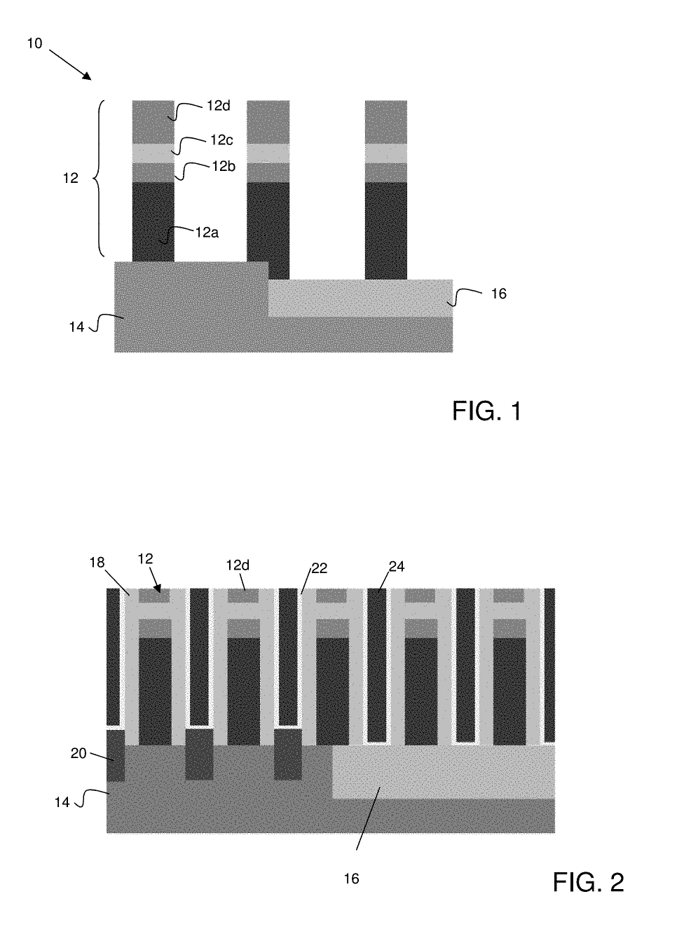

FIG. 1 shows a structure and respective fabrication processes in accordance with aspects of the disclosure. In particular, the structure 10 includes a plurality of dummy gate structures 12 formed on a fin structure 14 and over a shallow trench isolation (STI) structure 16. In embodiments, the fin structure 14 can be composed of any suitable semiconductor substrate material. For example, the substrate material can be, but not limited to, Si, SiGe, SiGeC, SiC, GaAs, InAs, InP, and other III/V or II/VI compound semiconductors. The STI structure 16 can be an oxide material deposited between adjacent fin structures 14.

In embodiments, the dummy gate structures 12 include a stack of materials 12a-12d deposited by conventional chemical vapor deposition (CVD) processes and patterned by conventional lithography and etching (reactive ion etching (RIE)) processes. For example, the stack of material includes, e.g., amorphous silicon (a-Si) material 12a, oxide material 12b, nitride material (e.g., SiN) 12c and oxide material 12d. In embodiments, the a-Si material 12a is a sacrificial material that is removed in later processes when forming a replacement gate structure. Also, in embodiments, the stack of materials can include a thin layer of dummy gate oxide below the a-Si material 12a (also represented by reference numeral 12a).

The thin layer of dummy gate oxide can have a thickness of about 3 nm. In embodiments, the a-Si material 12a can have a height of about 60 nm (compared to a height of >80 nm for conventional processes of record). In addition, the oxide material 12b can have a height of about 5 nm to 15 nm, the nitride material (e.g., SiN) 12c can have a height of about 10 nm to 30 nm and the oxide material 12d can have a height of about 0 to 50 nm. In embodiments, the combination of the oxide material 12b, the nitride material (e.g., SiN) 12c and the oxide material 12d can be about a hardmask module on the order of about 50 nm to 100 nm.

The fin structure 14 can be fabricated using a sidewall image transfer (SIT) technique. In an example of a SIT technique, a mandrel material, e.g., SiO₂, is deposited on the substrate material using conventional CVD processes. A resist is formed on the mandrel material, and exposed to light to form a pattern (openings). A reactive ion etching is performed through the openings to form the mandrels. In embodiments, the mandrels can have different widths and/or spacing depending on the desired dimensions between the fin structures 14. Spacers are formed on the sidewalls of the mandrels which are preferably material that is different than the mandrels, and which are formed using conventional deposition processes known to those of skill in the art. The spacers can have a width which matches the dimensions of the fin structures 14, for example. The mandrels are removed or stripped using a conventional etching process, selective to the mandrel material. An etching is then performed within the spacing of the spacers to form the sub-lithographic features. The sidewall spacers can then be stripped. In embodiments, the wide fin structures can also be formed during this or other patterning processes, or through other conventional patterning processes, as contemplated by the present disclosure.

Referring to FIG. 2, a spacer material 18 is deposited over the stack of materials (dummy gate structures) 12 using conventional CVD processes. In embodiments, the spacer material 18 is a nitride material, e.g., SiN, which is preferably the same material as the nitride material (e.g., SiN) 12c of the stack of materials 12. The spacer material 18 can be etched back using an anisotropic etching process to remove material from horizontal surfaces of the structure. For example, the anisotropic etching process will remove the spacer material 18 from the surface of the fin structure 14 and the top of the stack of material 12, e.g., over the oxide material 12d. In this etching process, some of the gate height (e.g., stack of material 12) will be lost due to the etching process.

Still referring to FIG. 2, raised source and drain structures 20 are formed on the exposed surfaces of the fin structure 14. In embodiments, the raised source and drain structures 20 can be formed by an epitaxial growth process of doped semiconductor material. For example, a SiGe material doped with boron can be used for the raised source and drain structure 20 of a PFET; whereas, a Si material doped with phosphorous can be used for the raised source and drain structure 20 of an NFET.

FIG. 2 further shows a liner 22 deposited over the spacer material 18 and the raised source and drain structures 20. In embodiments, the liner 22 is a nitride liner. Following deposition of the nitride liner 22, a-Si material 24 can be deposited over the liner 22, within spaces between the dummy gate structures 12, e.g., stack of materials. The structure can then undergo a chemical mechanical polishing (CMP) process to remove any excess material of a-Si material 24, as well as to remove liner material 22 on a top surface of the oxide material 12d.

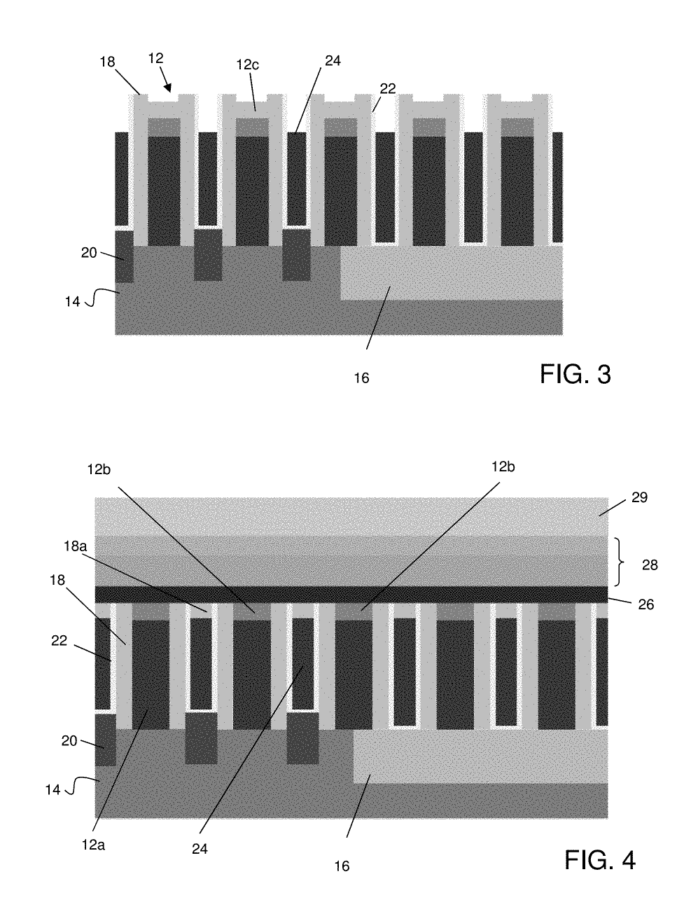

As shown in FIG. 3, the a-Si material 24 can be slightly recessed to below a top surface of the oxide material 12b. In embodiments, the recess can be about 15 nm to 30 nm; although other depths are contemplated herein. The a-Si material 24 can be recessed using a selective etching chemistry to the oxide material 12d. The oxide material 12d (e.g., hardmask material) can be removed by a selective etching chemistry, exposing the nitride material 12c.

In FIG. 4, a nitride material 18a is deposited on the nitride material 18 and within the recesses formed by the etching of the a-Si material 24. In embodiments, the nitride material 18a is deposited by an atomic layer deposition (ALD) process followed by a plasma enhanced CVD (PECVD) overfill process. The nitride material 18a is then planarized by a CMP process to the height of the oxide material (SiO₂) 12b. In embodiments, the CMP process can include a cobalt slurry, with the oxide material 12b acting as a hardmask stop layer. In this way, the CMP process will not affect the height of the a-Si layer 12a.

Following the CMP process, a layer of a-Si material 26 is deposited on the planarized surface, followed by deposition of hardmask materials 28 and a photoresist material 29. In embodiments, the layer of a-Si material 26 will be used to prevent damage to underlying layers during subsequent etching and cleaning processes. The a-Si material 26 can be deposited by a conventional CVD process. The hardmask materials 28 can include, e.g., optical sensitive material, e.g., (OPL) and low temperature oxide (e.g., SiCOH) or SiARC, or SiON, with the photoresist material 29 formed on a surface of the low temperature oxide material.

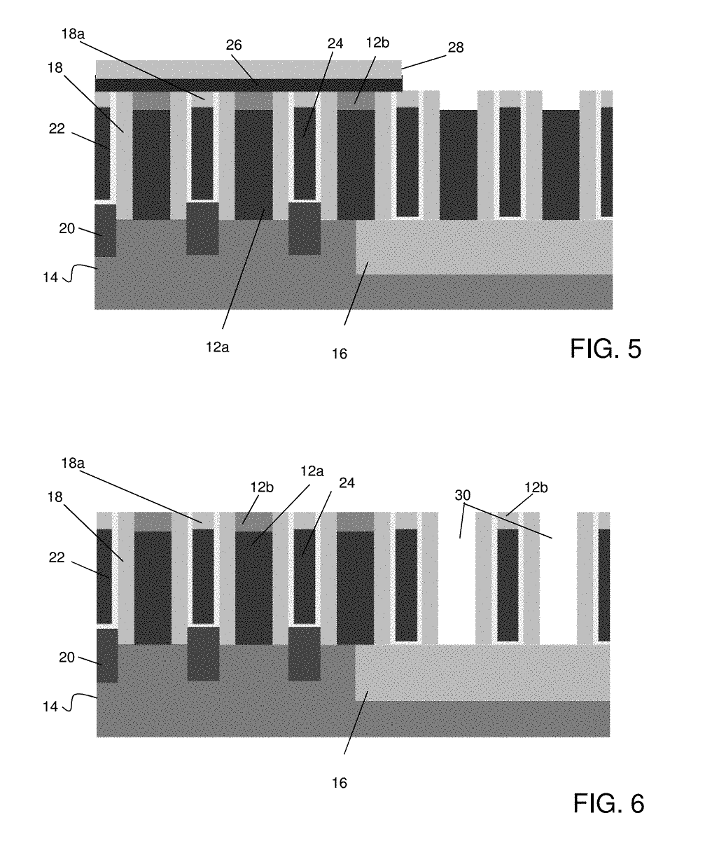

In FIG. 5, the resist material 29 can be exposed to energy to form a pattern, followed by a patterning of the hardmask materials 28. The patterning of the hardmask materials 28 can be performed by a selective etch chemistry, e.g., RIE process, with the layer of a-Si material 26 preventing any damage from occurring to the underlying material. Following resist removal by a conventional stripant process, e.g., oxygen ashing, a portion of the a-Si material 26 (over the STI region 16) can be removed to expose the oxide material 12b. In this process, the hardmask material (e.g., OPL) 28 will protect the a-Si material 26 from being removed over the fin structure 14. The exposed oxide material 12b will then be removed, forming a recess over the a-Si material 12a (over the STI region 16).

As shown in FIG. 6, the OPL 28 is removed by a conventional stripping process. Following the removal of the OPL 28, the a-Si material 26 and exposed a-Si material over the STI region 16 will also be removed, forming trenches 30. In embodiments, the a-Si material 26 and exposed a-Si material 12a can be removed by RIE process with a selective chemistry. In embodiments, the nitride material 18a and the oxide material 12b will act as a blocking material to protect the a-Si material 12a and a-Si material 24 over the fin region 14. The nitride material 18a will also act as a blocking material to protect the a-Si material 24 over the STI region 16 of the structure.

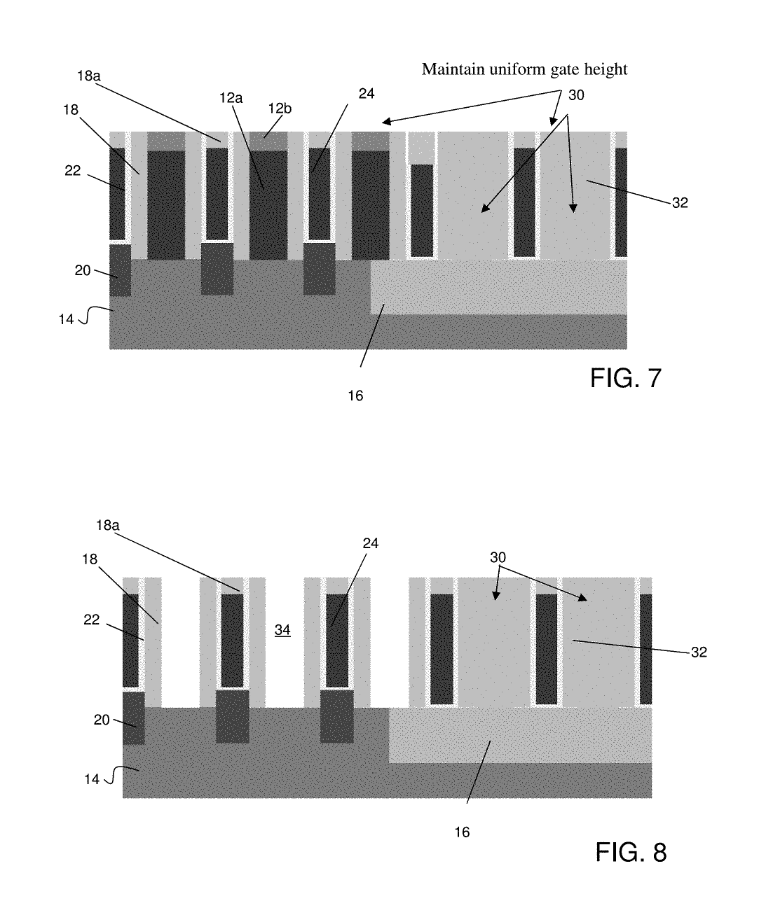

In FIG. 7, the trenches 30 are filled with material 32. In embodiments, the material 32 is nitride material, e.g., SiN, which is preferably the same material as the nitride material (e.g., SiN) of the spacers 18. In embodiments, the nitride material 32 is deposited by an atomic layer deposition (ALD) process followed by a plasma enhanced CVD (PECVD) overfill process. The nitride material 32 is then planarized by a CMP process to the height of the oxide material (SiO₂) 12b. In embodiments, the CMP process can include a cobalt slurry, with the oxide material 12b acting as a hardmask stop layer. In this way, the oxide material 12b will prevent material loss and hence provide additional gate height. Accordingly, a uniform gate height can be maintained across the wafer even after the CMP process.

Referring to FIG. 8, the oxide material 12b can be removed by a selective etch chemistry, e.g., using a buffered HF. Advantageously, the buffered HF will not significantly affect or damage the nitride material 18a formed over the a-Si material 24. In fact, as shown in FIG. 8, the a-Si material 24 is fully encapsulated in nitride material. Accordingly, there is no significant loss of initial gate height to removal of material during the dummy gate removal process.

Still referring to FIG. 8, the dummy gate material (a-Si and oxide material) is removed by a selective chemistry to form a trench 34, with the nitride material 18a, 32 substantially or completely maintaining its initial thickness; that is, the removal of the dummy gate material (a-Si and oxide material) will not significantly affect or damage the nitride material 18a, 32. In this way, there is no HF damage, e.g., no oxide height loss, and the gate height can remain uniform across the wafer. In embodiments, the trench 34 can have a height of more than 65 nm.

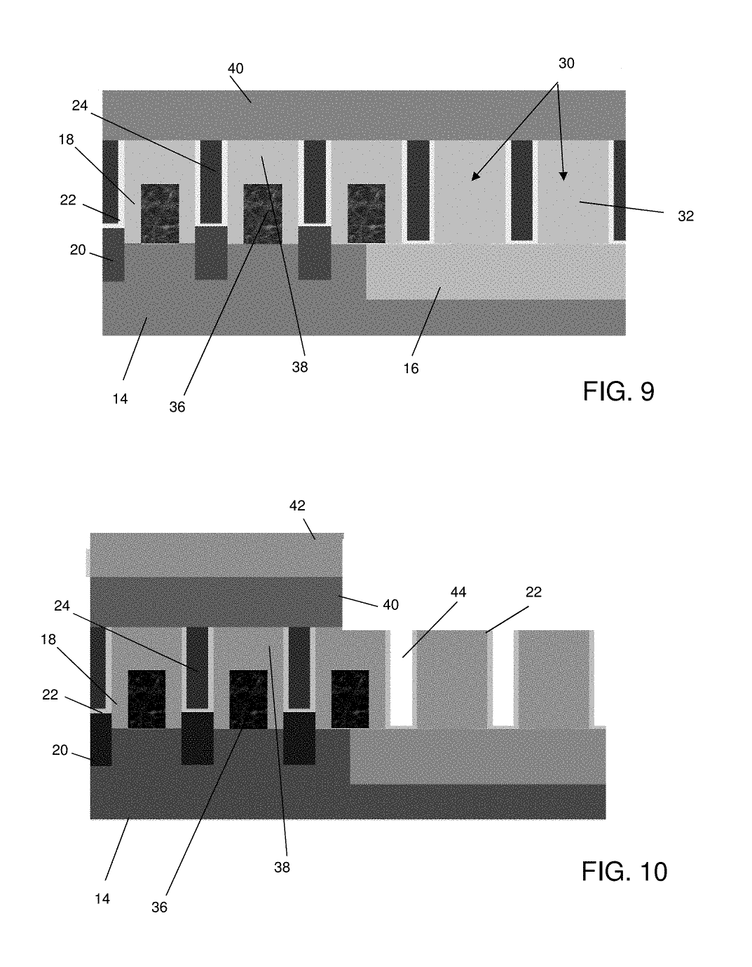

In FIG. 9, a replacement gate structure 36 can be deposited within the trench 34 using conventional deposition processes, e.g., CVD. In embodiments, the replacement gate material 34 can include, e.g., a high-k dielectric material, one or more tailored workfunction metals and other metal materials. In embodiments, the high-k dielectric material can be a hafnium based material, as an example. In embodiments, the total target height of the replacement gate structure 36 (including the capping material) has a total height of about 50 nm to about 60 nm; although other heights are also achievable implementing the processes described herein.

Following the deposition processes for replacement gate formation, the upper material layer of the replacement gate structure 36 can be recessed, followed by a deposition of a capping layer 38. In embodiments, the recess can be about 10 nm to about 25 nm, in depth. The capping material 38 is preferably a nitride material deposited by a conventional ALD and PECVD overfill process. Any excess capping material (or other materials) on the top surface of the structure can be removed by a CMP process. An interlevel dielectric material 40 can then be deposited on the planarized surface. In embodiments, the interlevel dielectric material 40 can be an oxide material deposited by a conventional CVD process.

FIG. 10 shows reverse patterning and etching processes in accordance with aspects of the present disclosure. More specifically, an optical sensitive material 42, e.g., (OPL), is deposited on the interlevel dielectric material 40, followed by conventional lithography and etching processes to form an opening over the STI region 16. The exposed interlevel dielectric material 40 is then removed by an oxide etch, followed by removal of the a-Si material 24 over the STI region 16 to form a trench 44. During the removal of the a-Si material with a selective chemistry, the interlevel dielectric material 40 will act as a masking material to prevent damage to underlying materials, e.g., nitride material 38 and a-Si material 24 over the fin structure 14.

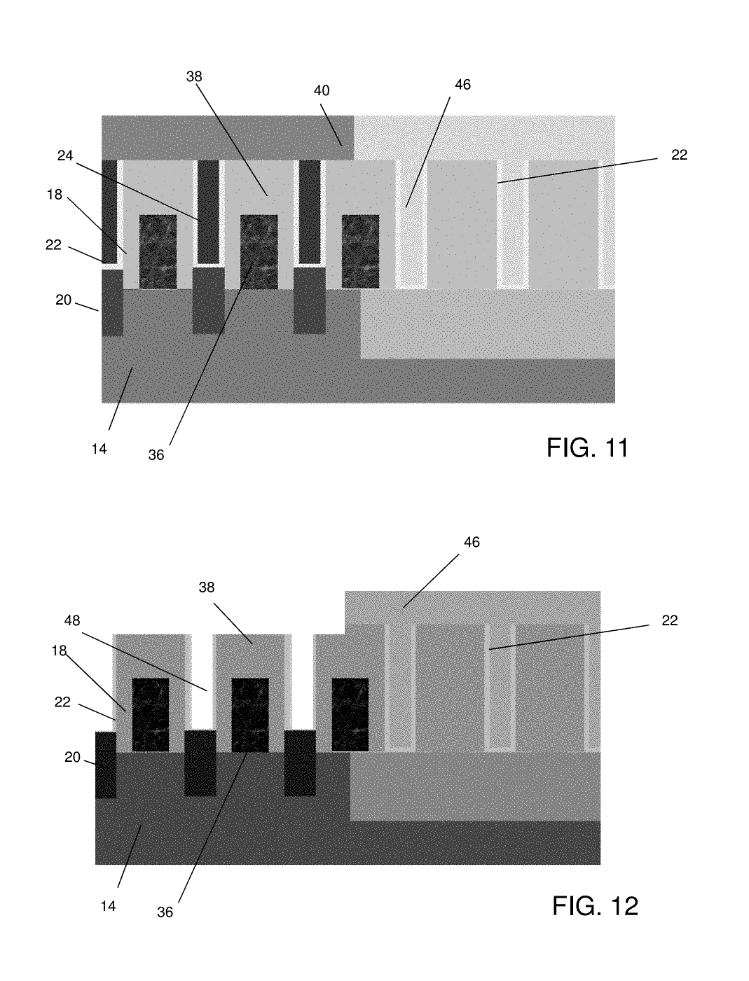

In FIG. 11, material 46 is deposited within the trenches 44 and surface of the structure. The material 46 can be SiOC, deposited using conventional CVD processes. In embodiments, the material 46 should be different than the oxide material 40 so that a selective removal of the oxide material 40 can be achieved in subsequent processes. The material 46 undergoes a CMP. In this way, the material 46 and the interlevel dielectric material 40 will have a planar surface, e.g., at a same height.

As shown in FIG. 12, the interlevel dielectric material 40 is removed using a selective chemistry. For example, the etch chemistry can be selective so as to not remove SiOC material. Following the removal of the interlevel dielectric material 40, exposed a-Si material over the raised source and drain regions 20 can be removed to form a trench 48. In embodiments, the exposed a-Si material can be removed by a gentle etching process, e.g., buffered HF, without damaging the nitride material. The removal of the a-Si material will not result in significant loss of material, e.g., thereby maintaining an initial gate height.

In embodiments, the liner material 22 can be removed over the capping material 38 and the surface of the raised source and drain regions 20 to expose the raised source and drain regions 20. In embodiments, the liner material 22 can be removed over the raised source and drain regions 20 and upper surface of the capping material 38 by an anisotropic etching process. The removal of the liner material 22 using an anisotropic etching process also will not result in significant loss of material.

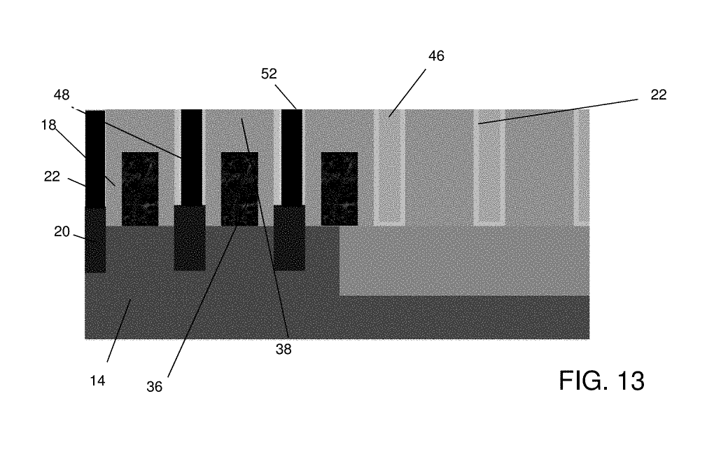

FIG. 13 shows contact formation on the raised source and drain regions 20. For example, as shown in FIG. 13, metal material 52 can be deposited within the trenches 48, in direct electrical contact with the raised source and drain regions 20. In embodiments, the metal material 52 can be tungsten, cobalt, lithium, etc., lined with TiN as an example. Any metal material deposited on the surface of the structure can be removed by a conventional CMP process.

The method(s) as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A method comprising:
forming at least one dummy gate structure comprising a sacrificial dummy gate material covered by a plurality of hardmask materials over the sacrificial dummy gate material;
forming a spacer material and a liner material on sidewalls of the at least one dummy gate structure, the liner material extending over source and drain regions on sides of the at least one dummy gate structure;
forming a plurality of materials over the liner on the source and drain regions on the sides of the at least one dummy gate structure;
removing upper materials of the plurality of hardmask materials and upper portions of the spacer material and the liner material such that a first material of the plurality of hardmask materials remains on the sacrificial material of the dummy gate structure and in combination with remaining portions of the spacer material, liner material and a blocking material of the plurality of materials maintains a uniform gate height;
forming a replacement gate structure by removing the first material and the sacrificial dummy gate material of the dummy gate structure to form a trench;
depositing replacement gate material in the trench; and
forming contacts to the source and drain regions.

2. The method of claim 1, further comprising forming a capping material over the replacement gate structure, prior to forming the contacts.

3. The method of claim 2, wherein:
the plurality of materials over the source and drain regions includes the sacrificial material and the blocking material over the sacrificial material, and
the blocking material and the first material of the plurality of hardmask materials are different materials.

4. The method of claim 3, wherein the removing of the remaining material of the dummy gate structure to form the trench comprises removing the first material and the sacrificial dummy gate material, while the blocking material remains on the sacrificial material to maintain the uniform gate height.

5. The method of claim 4, wherein the uniform gate height is about 65 nm.

6. The method of claim 4, wherein a height of the replacement gate structure is about 50 nm to about 60 nm.

7. The method of claim 4, wherein the blocking material is removed after formation of the capping material over the replacement gate structure.

8. The method of claim 3, wherein the sacrificial material and the capping material are different materials such that the sacrificial material can be selectively removed in order to form the contacts to the source and drain regions.

9. The method of claim 8, wherein the capping material maintains the gate height during the selective removing of the sacrificial material over the source and drain regions.

10. A method comprising:
forming at least one dummy gate structure comprising a sacrificial material of a predetermined height and a stack of hardmask materials on the sacrificial material;
forming a plurality of materials on source and drain regions on sides of the at least one dummy gate structure;
removing upper materials from the stack of hardmask materials, wherein a first material of the stack of hardmask materials remains on the sacrificial material and in combination with a blocking material of the plurality of materials maintains a uniform gate height;
exposing the sacrificial material of the at least one dummy structure by removing the first material, while the blocking material maintains the uniform gate height;
forming a replacement gate structure which comprises removing the sacrificial material to form a trench and depositing replacement gate material in the trench; and
forming contacts to the source and drain regions.

11. The method of claim 10, wherein the upper materials comprise a second material and a third material, the first material and the third material are an oxide material, and the second material is a different material than the first material and the second material.

12. The method of claim 10, wherein the sacrificial material is a-Si material.

13. The method of claim 12, wherein the predetermined height is approximately 60 nm.

14. The method of claim 10, wherein the blocking material and the first material of the stack of hardmask materials are different materials.

15. The method of claim 14, wherein the blocking material and the first material form a planar surface.

16. The method of claim 14, wherein the blocking material is a nitride material and the first material is an oxide material.

17. The method of claim 10, wherein the removing of the first material is performed by a selective chemistry which does not remove the blocking material.

18. The method of claim 17, wherein the removing is performed by a buffered solution.

19. The method of claim 18, wherein the replacement gate structure includes a capping material that maintains gate height during the selective removing of sacrificial material over the source and drain regions to form the contacts.

20. (canceled)

21. The method of claim 10, wherein:
the stack of hardmask materials comprising the first material, a second material and a third material;
the plurality of materials on the source and drain regions comprises:
a liner on a side of the at least one dummy gate structure and extending directly onto the source and drain regions; and
a sacrificial material on the liner;
the removing upper materials from the stack of hardmask materials comprising removing the third material and then the second material;
the blocking material is provided on the sacrificial material and between the liner of adjacent dummy gate structures; and
the uniform gate height is planar with the blocking material.
